(19) United States
(12) Patent Application Publication
(10) Pub. No.: US 2012/0252190 A1
(43) Pub. Date: Oct. 4, 2012

(54) Plasma Spraying with Mixed Feedstock

(75) Inventors: Raanan Y. Zehavi, San Jose, CA (US); Sharone Zehavi, San Jose, CA (US)

(73) Assignee: Integrated Photovoltaics, Inc., San Jose, CA (US)

(21) Appl. No.: 13/073,884

(22) Filed: Mar. 28, 2011

(51) Int. Cl. H01L 21/20; H01B 1/06

(52) U.S. Cl. 438/478; 252/521.3; 257/E21.09

(57) ABSTRACT

The instant invention discloses compositions for source material for a plasma spray gun comprising a Group IV based powder, optionally, a Group IV based liquid, optionally, a gas containing Group IV based gases, optionally a dopant, and a carrier gas, optionally, inert.

### CROSS-REFERENCE TO RELATED APPLICATIONS

This application is related in part to U.S. Pat. No. 7,789,331 and U.S. application Ser. Nos. 12/074,651, 12/720,153, 12/749,160, 12/789,357, 12/860,048, 12/860,088, 12/950,725, 13/010,700 and 13/019,965, and U.S. Provisionals 61/181,496 and 61/165,218, all owned by the same assignee and all incorporated by reference in their entirety herein. Additional technical explanation and background is cited in the referenced material.

### BACKGROUND OF THE INVENTION

1. Field of the Invention

The invention relates generally to plasma spraying to form thin film materials. In particular, the invention relates to plasma spraying of semiconductor-grade materials with a source material comprising a powder and optionally, one or more fluids, optionally, a liquid.

2. Description of Related Art

Plasma spraying of silicon has often been proposed for the formation of silicon semiconductor devices. Interest has been rekindled recently in plasma spraying of silicon to form inexpensive solar cells. To date, however, the technology has not been generally successful. We believe that several problems need to be solved in order to achieve economical plasma spraying of solar-grade silicon.

First, semiconductor-grade silicon must contain very low level of heavy metal impurities such as iron and copper. However, plasma spray guns typically have nozzles and electrodes formed of copper or stainless steel. In U.S. patent application publication 2008/0220558, R. Zehavi and J. Boyle describe a plasma gun having important portions composed of high-purity silicon. R. Zehavi has described an improved hybrid silicon nozzle for the plasma gun in U.S. application Ser. No. 12/720,153, filed 9 Mar. 2010. In some embodiments feedstock for a plasma spray comprises high-purity silicon powder produced in a jet mill, as described in U.S. Pat. No. 7,789,331, or in a silicon roller mill, as described in U.S. provisional application 61/165,218, filed 31 Mar. 2009. The latter reference also describes doping of the powder feedstock. Secondly, plasma spraying from silicon typically deposits the sprayed material, whether silicon or other material, as coins or lamellae. The individual coins are fairly homogeneous but voids are formed between the coins. It is believed that each coin arises from a single particle of silicon powder that is melted in the plasma plume and arrives at the substrate as a liquid drop, which quickly solidifies on the substrate with minimal interaction with the existing coins. Such a material needs to be recrystallized or annealed to homogenize the sprayed material and to remove the defects occurring in the gaps between the coins. R. Zehavi and S. Zehavi describe the coin structure and such a zone recrystallization apparatus and procedure in U.S. provisional application 61/181,496, filed 27 May 2009.

Prior art is found in Tamura, F., et al.; “Fabrication of poly-crystalline silicon films using plasma spray method”; Solar Energy Materials and Solar Cells 34 (1994) 263-270. Sinha, S. in U.S.2008/0023070 and Ervin, J. in 2010/0178435 disclose plasma spraying of liquid or gaseous silicon precursors. Additional prior art is found in U.S. Pat. No. 4,377,564; U.S.2008/0220558; U.S.2010/0200549; U.S. Pat. No. 6,265,288; U.S. 2002/0182769; and U.S. Pat. No. 4,772,564. Further improvements of the prior art are necessary to achieve low cost silicon deposition. References cited and in the IDS are incorporated herein by reference in their entirety.

### BRIEF SUMMARY OF THE INVENTION

The instant invention discloses compositions for source material for a plasma spray gun comprising a Group IV based powder, optionally, a Group IV based liquid, optionally, a gas containing Group IV based gases, optionally a dopant, and a carrier gas, optionally, inert. In some embodiments the instant invention discloses a method of supplying source material for a plasma spray gun comprising silicon powder, optionally, a liquid comprising silicon and, optionally, a gas containing silicon and a carrier gas, optionally, inert. Silicon is one exemplary powder disclosed by the instant invention; other powders disclosed include various Group IV elements, singly and in combination. All examples and embodiments disclosed herein apply to the various Group IV elements and mixtures thereof. In particular, the invention relates to a method and material composition for feedstock for a plasma spray gun for deposition of a layer of Group IV material, optionally, highly conductive, optionally, doped onto an, optionally, conductive substrate. In one embodiment, silicon powder, entrained in a silicon-based liquid, is injected into a plasma spray gun. The instant invention discloses a method for combining silicon powder and silicon liquid to maintain cleanliness of the silicon source material during the feed process with a carrier gas, optionally, inert, and a non-contaminating feed line to a plasma.

### DETAILED DESCRIPTION OF THE INVENTION

U.S. Ser. No. 12/074,651 describes one technique for injecting silicon powder for purposes of plasma spraying; alternative techniques are disclosed in the prior art. A recrystallization process is more effective if the coins as deposited are smaller since the included voids are smaller and smaller volumes need to be recrystallized. Accordingly, another feature of the invention utilizes a given size range for the silicon powder. For example, in some embodiments a silicon particle diameter size ranges from about 10 microns to about 75 microns; in some embodiments a silicon particle size ranges from about 50 microns to 100 microns; in some embodiments a silicon particle size range from about 10 microns to about 500 microns is preferred.

Further, injection of silicon powder inside the gun in a liquid stream in which the powder is entrained into the confined plasma flow increases the injection and utilisation efficiencies. However, the liquid needs to be non-contaminating for the semiconducting silicon being plasma sprayed. That is, the liquid should not be composed of compounds including any components considered to contaminate semiconducting silicon at significant fractions. Liquids containing carbon or oxygen, such as water or alcohol, especially isopropyl and methyl alcohol, are not considered appropriate for some applications or individual layers. Heavy metals are to be avoided as well.

Another feature of the invention includes entraining silicon powder in a liquid that is a compound of silicon and other components that volatize when separated from the silicon; exemplary other components include hydrogen and any of the halides. Especially useful are silicon compounds that are used as precursors to depositing silicon by chemical vapor deposition. One exemplary liquid precursor is trichlorosilane (SiHCl₃ or TCS). This material is widely used in the semiconductor industry, especially in the growth of electronic grade silicon (EGS) or more properly polysilicon by the Siemens process. However, other silicon precursors may be used; both liquid and gaseous compounds are candidates; preferred candidates are liquids whose boiling point is above room temperature or 20° C. and gaseous candidates that do not contain C, or 0; H, Br, F, Cl, S, N, and I are optional. Melting and boiling points of exemplary silicon compounds are listed in TABLE 1; additional silicon based compounds, both liquid and gaseous, are optional candidates.

Exemplary liquid silicon precursors are liquid at room temperature with a boiling point above 20° C. so that it does not vaporize in the injection system associated with the generally hot gun. Silicon based halogens, such as trichlorosilane, silicon tetrachloride, hexachlorodisilane and the more complex silicon hydrides such as trisilane and tetrasilane are liquid candidates. The silicon fluorides are widely used in semiconductor processing and tend to be gaseous at room temperatures. The silicon bromides offer relatively higher melting points. Silicon powder may be entrained in a liquid flow or a gas flow or both, thus allowing use of silicon powder of a range of diameters and the formation of smaller coins and smaller voids.

TABLE 1
Exemplary Carrier Fluid Compounds

| | Melting | | |
|---|---|---|---|
| | Point, | Boiling | |
| | ° C. | Point, ° C. | g Si/g |
| Si₄H₁₀ | −108 | 84 | 0.92 |
| Si₃H₈ | −117 | 52.9 | 0.91 |
| Si₂H₂I | −57 | 45 | 0.36 |
| SiH2Cl2 | −122 | 8.3 | 0.28 |
| Si₂Cl₆ | −1 | 145 | 0.21 |
| SiHCl3 | −126.6 | 31.8 | 0.21 |
| SiCl₄ | −70 | 57.6 | 0.17 |
| SiH2Br2 | −70 | 66 | 0.15 |
| SiBr4 | 5 | 154 | 0.08 |
| Si2H6 | −132 | −14.5 | 0.90 |
| SiH₄ | −185 | −111 | 0.87 |
| SiH₃Cl | −118.1 | −30.4 | 0.42 |
| Si₂F₆ | −18.7 | −18.5 | 0.33 |
| SiF₄ | −90 | −86 | 0.27 |
| Si₂Br₆ | 95 | 240 | 0.10 |

Similar compounds apply for carbon, germanium and tin.

Also, a fluid precursor can significantly contribute to the rate of deposition; liquid feedstock can deliver more silicon mass than gas feedstock. However, many advantages of the invention are produced by various combinations of gas, liquid and solid feedstock.

In some embodiments a plasma spray gun embodies elements of the instant invention. A similar, but not identical, gun is available from Sulzer Metco of Westbury, N.Y. as model F4-MB. Exemplary plasma guns are described in U.S. 2008/0220558 and U.S. Ser. No. 12/720,153, incorporated herein in their entirety by reference. As noted in U.S.2008/0220558 plasma guns as supplied by Sulzer do not conform to the inventions disclosed in U.S.2008/0220558 and herein.

The use of silicon-containing precursors in liquid or gaseous form allows for chemical vapor deposition (CVD) of silicon concurrently with the plasma spraying of silicon powder. CVD tends to deposit material in an even and continually developing coating. As a result, as soon as a coin of the powder is deposited, CVD silicon begins to form on it and to at least partially fill newly formed voids. Thus, density of a deposited silicon film is increased even if only a small fraction of the silicon is being deposited from gas and/or fluid precursors, jointly or combined with solid powder.

Alternative means for injecting may have the general form and structure of the hybrid nozzle of U.S. Ser. No. 12/720,153 including inserts of graphite and silicon; optionally, other designs may be used. In some embodiments, a portion of the gun may be formed of a homogenous material, for example, graphite. A gas feed may include argon for forming the plasma and some hydrogen or helium, for example, 10% hydrogen. In some embodiments the gas feed is excited into plasma in an annular gap and then enters as a plasma plume into a cylindrical exit bore extending along a nozzle axis. A plasma plume may exit an orifice with silicon liner of a nozzle as the free standing gun plume or flame directed at a substrate to be coated.

In some embodiments supply tubes are fixed to mixed feed ports by conventional tube fittings, such as Swagelock™ fittings, threaded into the threaded bores. Supply tubes are connected to a mixing chamber containing a mixture of silicon powder and a liquid silicon precursor such as TCS. Continuous agitation of the mixture may be utilised to prevent the silicon powder from settling out from the liquid. The feed rate of the mixed feedstock from a pre-mixer tank may be controlled by a needle valve at its outlet or by pressurizing the interior to a set slight positive level relative to the interior of the gun's exit bore with a gas, for example, argon, and then admitting additional argon into the mixing chamber through a mass flow controller at a controlled mass flow rate corresponding to the volume of mixed feedstock being delivered. In some embodiments the mixed feedstock is injected into plasma gun through a feedstock channel and enters a plasma plume. The liquid feedstock effectively entrains silicon powder as they both enter the plasma plume. In some embodiments an inclination assists the injection efficiency of the mixed feedstock into the plume. In some embodiments feedstock injection inside the exit bore is more efficient than injecting the feedstock into the gun flame outside a nozzle.

In some embodiments it is preferred to inject the Group IV, optionally, silicon, powder through different supply channels than mixed feedstock supply channels. It is also possible to supply a measured rate of liquid and a measured rate of powder into a common manifold, in which the two are mixed and immediately injected through one or more common injection ports.

Several embodiments of the invention inject solid and/or liquid and/or fluid components into multiple, optionally, alternative, locations in a plasma spray gun; optionally, a Group IV CVD precursor is not in liquid form. The invention enables plasma spraying of denser silicon films or layers and films which are easier to recrystallize. It also increases the injection efficiency of silicon; in some embodiments the injection efficiency is greater than 30%; in some embodiments the injection efficiency is greater than 75%. As used herein, injection efficiency is defined as the amount of source material, e.g. silicon, deposited divided by the amount injected. The liquid flow allows silicon powder to be effectively entrained and injected into a plasma stream and thus produces smaller coins and smaller voids. When a liquid of a silicon-precursor is used, the concomitant chemical vapor deposition of a silicon film further reduces the size of the voids. Accordingly, recrystallisation to produce a homogeneous silicon film is easier. The powder component of feedstock provides a high injection rate of silicon than do gaseous precursors and thus increases the deposition rate of silicon in a production environment.

In some embodiments silicon powder is of a diameter from about 25 microns to about 500 microns; in some embodiments silicon powder is of a diameter from about 25 microns to about 100 microns. In some embodiments silicon powder is not doped; in some embodiments at least a portion of the silicon powder is doped n-type; in some embodiments at least a portion of the silicon powder is doped p-type. In some embodiments silicon powder is mixed with carbon powder; in some embodiments silicon powder is mixed with carbon nanotubes. In some embodiments, a first component, silicon powder, optionally, a second component, a liquid comprising a silicon compound, and, optionally, a third component, a carbon compound, are source material to a plasma spray gun. In some embodiments the ratio of the three components to one another may vary in time such that the composition of a deposited layer changes as the layer becomes thicker; optionally, more than one plasma gun may be spraying a different composition based on layer thickness; optionally the powder composition and/or liquid component composition change over time with layer thickness such that regions of different composition and utility may be deposited. In some embodiments a silicon powder is one or more Group IV elements; optionally, germanium powder, carbon powder, tin powder, or silicon powder or mixtures of one or more powders; optionally, a Group IV powder may be a mixture of two or more Group IV elements. Optionally, a liquid component may be one or more Group IV based liquids; optionally, a third component may be one or more Group IV based gaseous compounds.

In some embodiments a method of plasma spraying a Group IV material comprises the steps: mixing a Group IV powder with a Group IV carrier fluid compound; injecting the Group IV powder entrained in the Group IV carrier fluid into a plasma; and depositing the Group IV material onto a surface; optionally, the Group IV powder has a particle diameter of more than 10 microns; optionally, the Group IV carrier fluid compound is at least one of a liquid or gaseous Group IV compound consisting of one or more Group IV elements and one or more elements chosen from a group consisting of H, S, N, Cal, Br, F, I; optionally, the Group IV powder is exposed to air for less than two hours before mixing with the Group IV carrier fluid compound; optionally, the carrier fluid and the Group IV powder are mixed at a ratio between about 2% to 40% by weight of the Group IV powder to Group IV carrier fluid compound weight plus Group IV powder weight; optionally, the Group IV powder and Group IV carrier fluid compound after being mixed contain more than 5% by weight of silicon; optionally, a Group IV powder consists of particles wherein one or more elements from Group IV are in each particle or as a mixture of particles wherein each particle consists of only one Group IV element; optionally, the Group IV material changes in composition based upon the duration of the depositing step; optionally, at least a portion of the Group IV powder contains a p-type or n-type dopant.

In some embodiments a Group IV composition for injecting into a plasma gun consists of: a Group IV powder; and a Group IV carrier fluid compound wherein the Group IV powder is of a diameter between about 10 microns and 500 microns and the Group IV carrier fluid and the Group IV powder are mixed at a ratio between about 2% to 40% by weight Group IV powder to Group IV carrier fluid compound weight plus Group IV powder weight; optionally, the Group IV carrier fluid compound consists of one or more Group IV elements and one or more elements chosen from a group consisting of H, S, N, Cl, Br, F, and I; optionally, the rate of injection of Group IV elements into the plasma gun is between about 1 g/min and about 150 g/min; optionally, the of Group IV powder and Group IV carrier fluid compound after being mixed contact only materials chosen from a group consisting of glass, alumina, graphite, silicon, silicon carbide, metal carbides and metal nitrides before being injected; optionally, the Group IV powder and Group IV carrier fluid compound after being mixed contain more than 5% by weight of silicon; optionally, at least a portion of the Group IV powder contains a p-type or n-type dopant; optionally, at least a portion of the Group IV carrier fluid compound contains a p-type or n-type dopant.

It will be understood that when an element as a layer, region or substrate is referred to as being “on” or “over” or “adjacent” another element, it can be directly on the other element or intervening elements may also be present. In contrast, when an element is referred to as being “directly on” or “directly over” or “in contact with” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

The foregoing described embodiments of the invention are provided as illustrations and descriptions. They are not intended to limit the invention to a precise form as described. In particular, it is contemplated that functional implementation of invention described herein may be implemented equivalently in various combinations or other functional components or building blocks. Other variations and embodiments are possible in light of above teachings to one knowledgeable in the art of semiconductors, thin film deposition techniques, and materials; it is thus intended that the scope of invention not be limited by this Detailed Description, but rather by Claims following.

We claim:

1. A method of plasma spraying a Group IV material comprising the steps:
mixing a Group IV powder with a Group IV carrier fluid compound;
injecting the Group IV powder entrained in the Group IV carrier fluid into a plasma; and
depositing the Group IV material onto a surface.

2. The method of claim 1, wherein the Group IV powder has a particle diameter of more than 10 microns.

3. The method of claim 1, wherein the Group IV carrier fluid compound is at least one of a liquid or gaseous Group IV compound consisting of one or more Group IV elements and one or more elements chosen from a group consisting of H, S, N, Cl, Br, F, I.

4. The method of claim 1 wherein the Group IV powder is exposed to air for less than two hours before mixing with the Group IV carrier fluid compound.

5. The method of claim 1 wherein the carrier fluid and the Group IV powder are mixed at a ratio between about 2% to 40% by weight of the Group IV powder to Group IV carrier fluid compound weight plus Group IV powder weight.

6. The method of claim 1 wherein the Group IV powder and Group IV carrier fluid compound after being mixed contain more than 5% by weight of silicon.

7. The method of claim 1 wherein the Group IV powder consists of particles wherein one or more elements from Group IV are in each particle or as a mixture of particles wherein each particle consists of only one Group IV element.

8. The method of claim 1 wherein the Group IV material changes in composition based upon the duration of the depositing step.

9. The method of claim 1 wherein at least a portion of the Group IV powder contains a p-type or n-type dopant.

10. A Group IV composition for plasma spraying consisting of:
a Group IV powder; and
a Group IV carrier fluid compound wherein the Group IV powder is of a diameter between about 10 microns and 500 microns and the Group IV carrier fluid and the Group IV powder are mixed at a ratio between about 2% to 40% by weight Group IV powder to Group IV carrier fluid compound weight plus Group IV powder weight.

11. The composition of claim 10 wherein the Group IV carrier fluid compound consists of one or more Group IV elements and one or more elements chosen from a group consisting of H, S, N, Cl, Br, F, and I.

12. The composition of claim 10 wherein the rate of injection of Group IV elements for plasma spraying is between about 1 g/min and about 150 g/min.

13. The composition of claim 10 wherein the of Group IV powder and Group IV carrier fluid compound after being mixed contact only materials chosen from a group consisting of glass, alumina, graphite, silicon, silicon carbide, metal carbides and metal nitrides before being injected.

14. The composition of claim 10 wherein the Group IV powder and Group IV carrier fluid compound after being mixed contain more than 5% by weight of silicon.

15. The composition of claim 10 wherein at least a portion of the Group IV powder contains a p-type or n-type dopant.

16. The composition of claim 10 wherein at least a portion of the Group IV carrier fluid compound contains a p-type or n-type dopant.
